(19) United States
(12) Patent Application Publication
(10) Pub. No.: US 2014/0021655 A1
(43) Pub. Date: Jan. 23, 2014

(54) DRAWING APPARATUS, TRANSMISSION APPARATUS, RECEIVING APPARATUS, AND METHOD OF MANUFACTURING ARTICLE

(71) Applicant: CANON KABUSHIKI KAISHA, Tokyo (JP)

(72) Inventors: Yoshihiro Hirata, Utsunomiya-shi (JP); Hiro Norikane, Utsunomiya-shi (JP)

(21) Appl. No.: 13/942,086

(22) Filed: Jul. 15, 2013

(30) Foreign Application Priority Data
Jul. 17, 2012 (JP) 2012-158514

(51) Int. Cl. H01J 37/304; H04B 10/69; H04B 10/58

(52) U.S. Cl. CPC H01J 37/304; H04B 10/58; H04B 10/697
USPC 264/406; 398/192; 398/208; 425/135

(57) ABSTRACT

A drawing apparatus that performs drawing on a substrate with a plurality of charged particle beams includes a blanker array configured to blank the plurality of charged particle beams, respectively; a generating device configured to generate a blanking signal for controlling the blanker array and an error detection signal for the blanking signal; and a plurality of transmission paths for transmitting signals between the generating device and the blanker array. The plurality of transmission paths include a first transmission path for transmitting the blanking signal and a second transmission path for transmitting the error detection signal. The generating device is configured to transmit a blanking signal and an error detection signal corresponding to the blanking signal via the first transmission path and the second transmission path, respectively, to the blanker array in parallel.

### BACKGROUND OF THE INVENTION

1. Field of the Invention

The present invention relates to a drawing apparatus, a transmission apparatus, a receiving apparatus, and a method of manufacturing an article.

2. Description of the Related Art

A drawing apparatus that performs drawing on a substrate with a plurality of electron beams is known. In such a drawing apparatus, the plurality of electron beams is blanked individually. Thus, along with an increase in the number of electron beams and an increase in the blanking frequency, the transmission rate of blanking signals needs to be increased. For example, to draw a target drawing pattern with a half pitch of 32 nm on ten or more wafers per hour, the transmission rate of the blanking signals may reach up to a few T bps. In such a case, even when an optical fiber with a transmission speed of, for example, 4 G bps is used, a few thousands (a few thousands channels) of optical fibers are required for serial communication between a blanking signal generation unit and a blanking deflector.

In such serial communication, if an error occurs in a received blanking signal due to noise being mixed therein, a timing deviation, and so on, proper blanking cannot be carried out, which may lead to improper drawing resulting from a drawing position or a dose amount being deviated. Further, with an increase in the transmission amount of blanking signals, the rate of error occurrence in the communication of the blanking signals may also increase. To date, error detection in the communication is carried out at a receiving side using an error detection code (also referred to an error detection signal), such as a parity bit and a cyclic redundancy check (CRC) being added to a transmission signal. Further, if an error is detected, the receiving side may request the signal in which the error has occurred to be re-transmitted. International Publication No. 2006/104139 (in paragraph 0053) discusses a technique in which when a receiving side of exposure data detects a data transmission error from data for carrying out error detection, the receiving side requests a transmitting side to re-transmit the data.

In production equipment such as a semiconductor manufacturing apparatus, not only a yield rate but also throughput (operation rate) is important. Accordingly, in an electron beam drawing apparatus, a delay time when an error occurs in a blanking signal can be an issue. However, if an existing method as described above is applied to the drawing apparatus, blanking signals 1-1, 1-2, and 1-3 and a first error detection signal generated based on the blanking signals 1-1, 1-2, and 1-3 are transmitted in series through the same transmission path, as illustrated in FIG. 6A. Then, it takes time for all the information necessary for error detection to be collected in an error detection unit 4, and thus it takes time to detect an error. As a result, it takes time to obtain an error-free blanking signal after re-transmission.

On the other hand, as illustrated in FIG. 4B, if an error detection signal is divided into smaller pieces and added to the blanking signals, time required for the blanking signals and the error detection signal necessary for error detection to be collected in the error detection unit 4 can be shortened. For example, error detection can be carried out when a blanking signal 1-1 and a first error detection signal generated based on the blanking signal 1-1 are collected, and thus error detection becomes possible at an earlier time. However, an increase in the error detection signals leads to an increase in time required for transmitting the blanking signals, which affects the throughput.

### SUMMARY OF THE INVENTION

The present invention is directed to, for example, a drawing apparatus having an advantage in throughput even with a communication error.

According an aspect of the present invention, a drawing apparatus that performs drawing on a substrate with a plurality of charged particle beams, includes a blanker array configured to blank the plurality of charged particle beams, respectively; a generating device configured to generate a blanking signal for controlling the blanker array and an error detection signal for the blanking signal; and a plurality of transmission paths for transmitting signals between the generating device and the blanker array, wherein the plurality of transmission paths include a first transmission path for transmitting the blanking signal and a second transmission path for transmitting the error detection signal, and wherein the generating device is configured to transmit a blanking signal and an error detection signal corresponding to the blanking signal via the first transmission path and the second transmission path, respectively, to the blanker array in parallel.

Further features of the present invention will become apparent from the following description of exemplary embodiments with reference to the attached drawings.

### BRIEF DESCRIPTION OF THE DRAWINGS

FIG. 1 illustrates a configuration of a drawing apparatus according to a first exemplary embodiment of the present invention.

FIG. 2 illustrates a configuration of a blanker array (blanking deflector) according to the first exemplary embodiment.

FIG. 3 illustrates a configuration pertaining to a blanking function including signal transmission according to the first exemplary embodiment.

FIGS. 4A and 4B illustrate configuration examples of a main portion according to the first exemplary embodiment and signal transmission therein.

FIG. 5 illustrates a configuration example of a main portion according to a second exemplary embodiment of the present invention and signal transmission therein.

FIGS. 6A and 6B illustrate comparative examples of a configuration of a transmission path according to a third exemplary embodiment.

### DESCRIPTION OF THE EMBODIMENTS

Hereinafter, exemplary embodiments of the present invention will be described with reference to the accompanying drawings. In the drawings for describing the exemplary embodiments, as a general rule, identical members are given to identical reference characters, and duplicate descriptions thereof will be omitted.

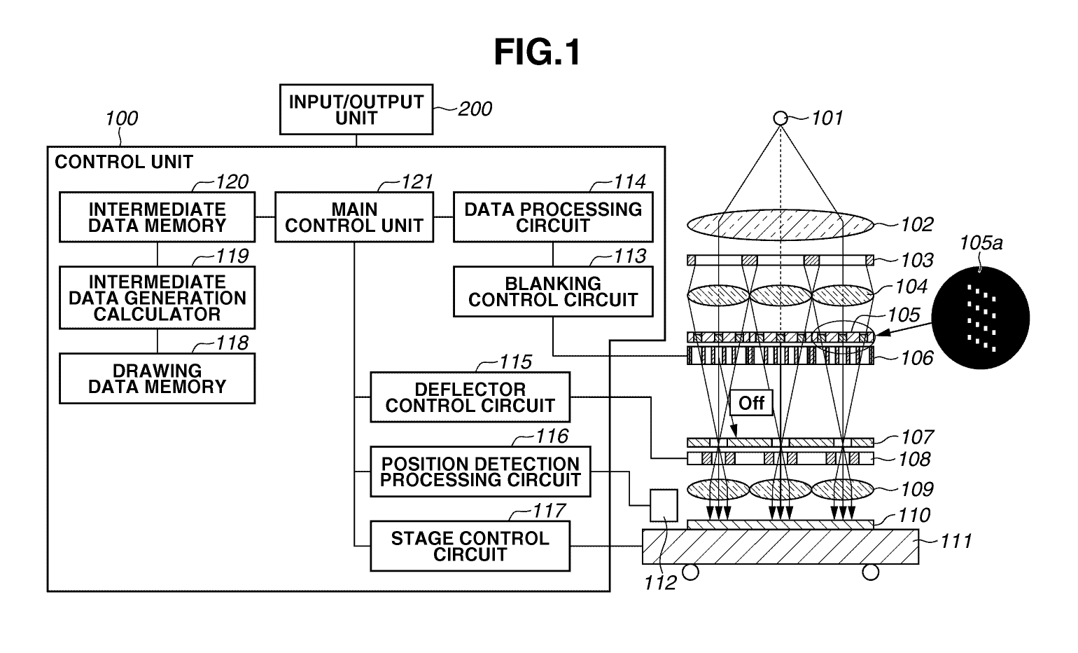

FIG. 1 illustrates a configuration of a drawing apparatus according to a first exemplary embodiment of the present invention. With reference to FIG. 1, an electron source 101 may be of a thermal electron type, which includes LaB₆, BaO/W (dispenser cathode), or the like as an electron emitting material. A collimator lens 102 may be an electrostatic lens that converges an electron beam through an electric field. An electron beam emitted from the electron source 101 is turned into a substantially parallel electron beam by the collimator lens 102. Although the drawing apparatus in the exemplary embodiment performs drawing on a substrate with a plurality of electron beams, charged particle beams such as ion beams aside from the electron beams may also be used, and the exemplary embodiment can be applied generally to a drawing apparatus that performs drawing on a substrate with a plurality of charged particle beams.

An aperture array (aperture array member) 103 includes two-dimensionally arranged apertures. A condenser lens array 104 includes two-dimensionally arranged electrostatic condenser lenses with the same optical power. A pattern aperture array (aperture array member) 105 includes arrays of pattern apertures (sub-arrays) for defining, or determining, the shape of the electron beams. The arrays of the patterned apertures are provided to correspond to the respective condenser lenses. Each sub-array has a pattern 105a when viewed from above.

The substantially-parallel electron beam from the collimator lens 102 is divided into a plurality of electron beams by the aperture array 103. The divided electron beams illuminate the respective sub-arrays in the pattern aperture array 105 through the respective condenser lenses in the condenser lens array 104. Here, the aperture array 103 has a function of defining the range of such illumination.

A blanker array (also referred to as a blanking deflector) 106 includes electrostatic blankers (electrode pair) that can be individually driven, and the blankers are arranged to correspond to the respective electron beams. A blanking aperture array 107 includes blanking apertures that are arranged to correspond to the respective condenser lenses. A deflector array 108 includes deflectors for deflecting the electron beams in a predetermined direction, and the deflectors are arranged to correspond to the respective condenser lenses. An objective lens array 109 includes electrostatic objective lenses that are arranged to correspond to the respective condenser lenses. Drawing (exposure) is performed on a wafer (substrate) 110. In the above configuration example of the first exemplary embodiment, the components 101 to 109 described above constitute an electron optical system (charged electron optical system) that generates a plurality of electron beams (charged particle beams) for performing drawing on the substrate.

Electron beams illuminating and passing through the sub-arrays of the pattern aperture array 105 pass through the blankers, the blanking apertures, the deflectors, and the objective lenses, and each electron beam is reduced to one-hundredth of its original size and projected onto the wafer 110. Here, with a plane along which the pattern apertures are arranged in the sub-arrays being an object plane, an upper surface of the wafer 110 lies along the image plane corresponding to the stated object plane.

Whether each of the electron beams that has illuminated and passed through the sub-arrays of the pattern aperture array 105 passes through the respective blanking apertures in the blanking aperture array 107 is controlled by controlling the respective blankers of the blanker array 106. That is, whether each of the electron beams is incident on the wafer 110 can be switched by controlling the respective blankers. Those electron beams that are incident on the wafer 110 scan the wafer 110 collectively through the deflector array 108.

The electron beams from the electron source 101 are imaged on the blanking apertures through the collimator lens 102 and the condenser lenses, and the size of each of the imaged electron beams is set to be larger than the aperture of the blanking apertures. Accordingly, the semi-angle of the electron beam on the wafer 110 is determined by the aperture of the blanking apertures. In addition, the aperture of the blanking apertures are positioned to correspond to anterior focal points of the corresponding objective lenses, and thus principal rays of the plurality of electron beams from the plurality of pattern apertures of the sub-arrays are incident substantially normally onto the wafer 110. Therefore, even if the upper surface of the wafer 110 is vertically displaced, displacement of the electron beams along the horizontal plane is subtle.

An X-Y stage (also referred to simply as a stage) 111 holds the wafer 110 and is movable along the X-Y plane (horizontal plane) that is orthogonal to the optical axis. The stage 111 includes a chuck (not illustrated) for holding (attracting) the wafer 110 and a detector (not illustrated) for detecting the electron beams. The detector includes an aperture pattern into which the electron beams enter. A mark detector 112 applies light onto a positioning mark formed on the wafer 110 at a wavelength at which the resist is not exposed and then detects a reflection image of the positioning mark with an image sensor.

A blanking control circuit 113 (also referred to as a blanking signal generation unit or simply as a generation unit) controls individually the plurality of blankers of the blanker array 106. A data processing circuit 114 includes a buffer memory and generates control data of the blanking control circuit 113. A deflector control circuit 115 controls the plurality of deflectors of the deflector array 108 through a common signal. A position detection processing circuit 116 obtains the position of a mark based on a signal from the mark detector 112 and detects misalignment of each shot based on the obtained position of the mark. A stage control circuit 117 controls positioning of the stage 111 in cooperation with a laser interferometer (not illustrated) for measuring the position of the stage 111. A drawing data memory 118 stores drawing data for each shot. An intermediate data generation calculator 119 generates intermediate stripe data (intermediate data) from the drawing data to correct shot misalignment. An intermediate data memory 120 stores the intermediate data.

A main control unit 121 transfers the intermediate data to the buffer memory of the data processing circuit 114 and also integrally controls the drawing apparatus by controlling the circuits and the memories described above. Although a control unit 100 of the drawing apparatus of the first exemplary embodiment includes the components 113 to 121, this configuration is merely an example, and modifications can be made as appropriate.

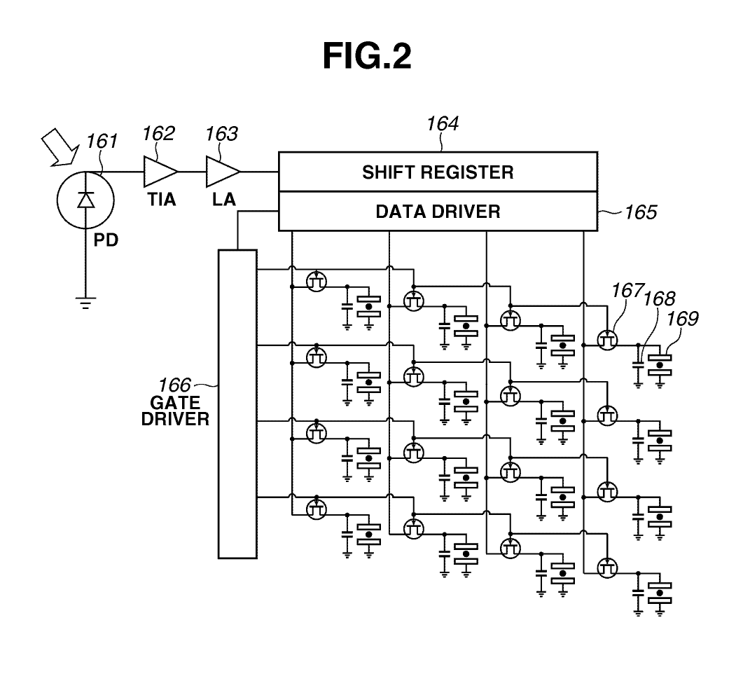

FIG. 2 illustrates the configuration of the blanker array 106. The blanking control circuit 113 supplies a control signal to the blanker array 106 through an optical fiber (not illustrated) for optical communication. A single optical fiber transmits control signals for a plurality of blankers corresponding to one sub-array. A photodiode 161 receives an optical signal from the optical fiber for optical communication. A transfer impedance amplifier 162 subjects the optical signal to current to voltage conversion. Then, a limiting amplifier 163 adjusts the amplitude of the converted optical signal. A shift register 164 receives the signal whose amplitude has been adjusted and converts the received serial signal into a parallel signal. A field-effect transistor (FET) 167 is provided at each intersection of a horizontally running gate electrode wire and a vertically running source electrode wire, and two bus wires are connected respectively to a gate and a source of the FET 167. A blanker electrode 169 and a capacitor 168 are connected to a drain of the FET 167, and each of these two capacitive elements is connected to a common electrode at the opposite side of the FET 167. When a voltage is applied to a given gate electrode wire, the entire row of the FETs 167 connected to that gate electrode wire are turned on, and thus a current flows between the source and the drain. At that time, a voltage being applied to each source electrode wire is applied to the blanker electrode 169, and thus a charge corresponding to that voltage accumulates (or is charged) in the capacitor 168. When one gate electrode wire finishes charging for a given row, a voltage is then applied to another gate electrode wire. Thus, the FETs 167 connected to the aforementioned one gate electrode wire lose the gate voltage and thus are turned off. At this time, although the blanker electrodes 169 connected to the aforementioned one gate electrode wire lose the voltage from the source electrode wires, the blanker electrodes 169 can retain a necessary voltage with the charge accumulated in the capacitors 168 until a voltage is applied to a subsequent gate electrode wire. In this way, with an active matrix drive system with an FET being used as a switch, voltages can be applied to a plurality of FETs in parallel through a gate electrode wire, and thus an increase in the number of blankers can be handled with a small number of wires.

In the example illustrated in FIG. 2, the blankers are arranged in 4 rows by 4 columns. A parallel signal from the shift register 164 is applied as a voltage to a source electrode of the FET 167 through a data driver 165 and the source electrode wire. In cooperation with the above, the FETs 167 on the entire row are turned on as a gate driver 166 applies a voltage, and thus the entire blankers on the corresponding row are controlled. Such an operation is sequentially carried out for each row to control the blankers arranged in 4 rows by 4 columns

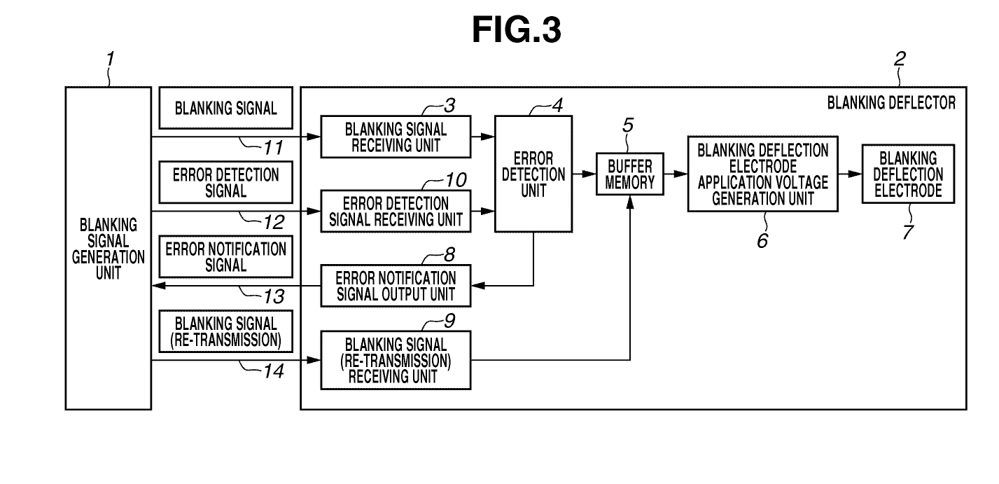

FIG. 3 illustrates a configuration pertaining to a blanking function including signal transmission in the first exemplary embodiment. A blanking deflector 2 is controlled through a blanking signal generated by a blanking signal generation unit 1 (also referred to simply as a generation unit). Note that the blanking signal generation unit 1 corresponds to the blanking control circuit 113 in FIG. 1, and the blanking deflector 2 corresponds to the blanker array 106 in FIG. 1. The blanking signal generation unit 1 is disposed outside an electron optical system lens barrel (not illustrated), and the blanking deflector 2 is disposed inside the electron optical system lens barrel. The blanking signal generation unit 1 and the blanking deflector 2 are connected to each other through an optical fiber or through transmission paths 11, 12, 13, and 14 (serial transmission paths) that are illustrated coaxially.

The blanking deflector 2 includes a blanking signal receiving unit 3, an error detection unit 4, an error notification signal output unit 8, a blanking signal re-transmission receiving unit 9, an error detection signal receiving unit 10, and a buffer memory 5. The blanking deflector 2 further includes a blanking deflection electrode application voltage generation unit 6 (also referred to simply as an application voltage generation unit) and a blanking deflection electrode 7. The blanking deflection electrode application voltage generation unit 6 corresponds to the components 164 to 168 in FIG. 2, and the blanking deflection electrode 7 corresponds to the blanker electrode 169 in FIG. 2.

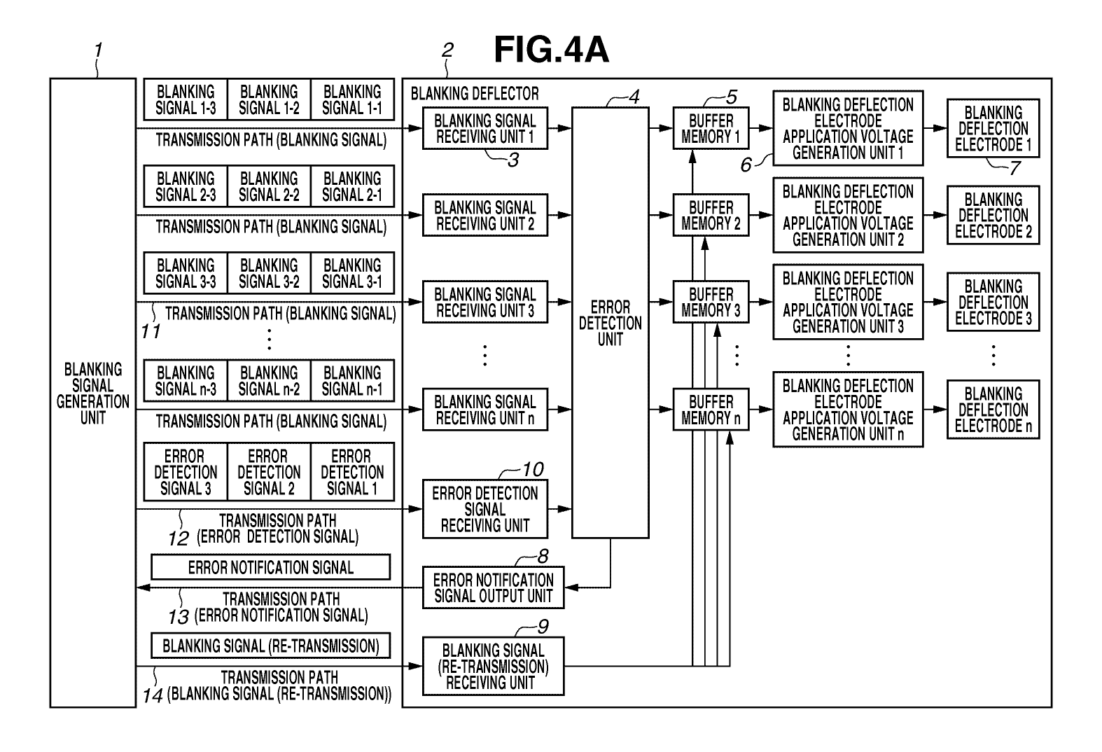

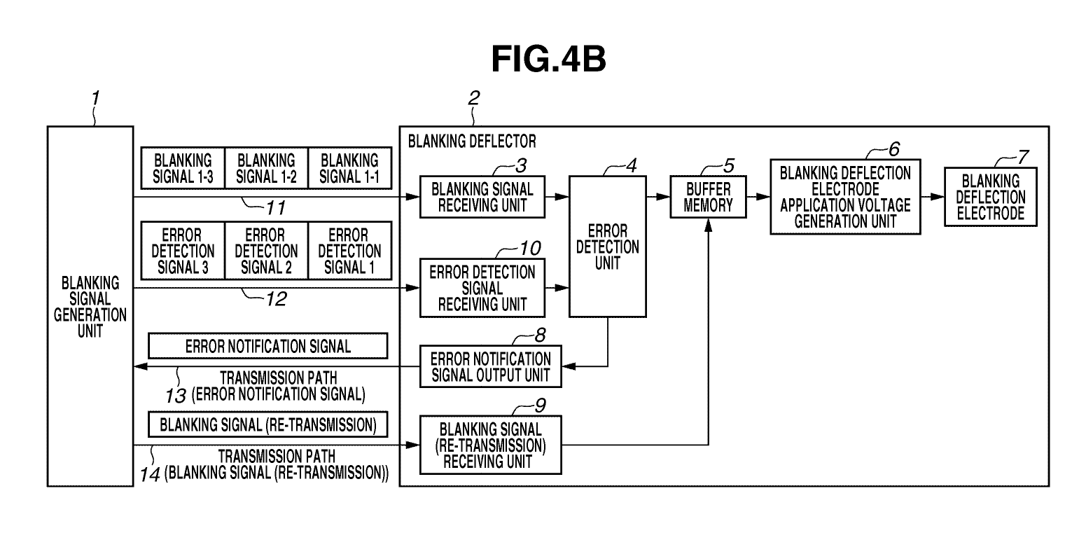

A method for transmitting a blanking signal and an error detection signal in the first exemplary embodiment will now be described with reference to FIGS. 4A and 4B. FIGS. 4A and 4B illustrate configuration examples of a main portion according to the first exemplary embodiment and the signal transmission therein. FIG. 4A illustrates various signals generated by the blanking signal generation unit 1 and the blanking deflector 2 and transmission of these signals. The blanking signal generation unit 1 first generates blanking signals to be transmitted to the respective transmission paths 11. The blanking signal generation unit 1 also generates error detection signals that respectively correspond to the plurality of blanking signals to be transmitted to the plurality of transmission paths 11. For example, if there are three transmission paths 11 for transmitting the blanking signals (also referred to as a first transmission path) (i.e., n=3), the blanking signal generation unit 1 generates a first error detection signal for blanking signals 1-1, 2-1, and 3-1. Similarly, the blanking signal generation unit 1 generates a second error detection signal for blanking signals 1-2, 2-2, and 3-2 and generates a third error detection signal for blanking signals 1-3, 2-3, and 3-3.

Then, the blanking signal generation unit 1 transmits the first to third error detection signals to the error detection signal receiving unit 10 in parallel with the blanking signals through the transmission path 12 that is dedicated for transmitting the error detection signals (also referred to as a second transmission path) and that is distinct from the transmission path 11 for transmitting the blanking signals. Here, each blanking signal and each error detection signal may have the same data length and may be transmitted in synchronization with each other. For example, each of the blanking signals 1-1, 2-1, and 3-1 and the first error detection signal may have the same data length and may be transmitted in synchronization with each other. An error detection signal may be generated to include only a signal of an error detection code such as a parity bit or a CRC for each corresponding blanking signal. Further, if there is room in the data length of an error detection signal, the error detection signal may be generated such that other information such as an identification signal of the blanking signal is added thereto, and if necessary, a dummy code is further added thereto so that the data length of the error detection signal coincides with the data length of the blanking signal.

Then, the blanking signal receiving unit 3 and the error detection signal receiving unit 10 can receive the blanking signals 1-1, 2-1, and 3-1 and the first error detection signal, respectively, in parallel and transmit the received information pieces in parallel to the error detection unit 4. Accordingly, in comparison with the case where the blanking signals and the error detection signal are transmitted and received in series, time required for the error detection unit 4 to detect an error can be reduced. Further, the components of the error detection unit 4 that have been provided for the respective transmission paths can be integrated into a component to be shared by a plurality of transmission paths, and thus the circuit size for the error detection unit 4 can be reduced.

In the description above, the ratio of the number of transmission paths 11 for the blanking signals to the number of transmission paths 12 for the error detection signals is n to 1 (n is an integer equal to or greater than 2), but the present exemplary embodiment is not limited thereto. If there is room in the number of transmission paths or in the circuit size, the ratio of the number of transmission paths 11 for the blanking signals to the number of transmission paths 12 for the error detection signals may be set to 1 to 1, as in the configuration illustrated in FIG. 4B. This configuration also has advantages in time required for detecting an error, similarly to the configuration illustrated in FIG. 4A.

Subsequently, re-transmission of a blanking signal in which an error has occurred will be described. If the error detection unit 4 detects an error, the error notification signal output unit 8 transmits an error notification signal to the blanking signal generation unit 1 through the transmission path 13. Based on this error notification signal, the blanking signal generation unit 1 can identify (recognize) blanking data in which the error has occurred. Such identification may be realized by the error notification signal output unit 8 transmitting the error notification signal that includes identification information of the blanking signal in which the error has occurred. Alternatively, each time the blanking deflector 2 receives a blanking signal, the blanking deflector 2 may transmit an error non-detection notification signal if an error is not detected, or transmit an error detection notification signal as an error notification signal if an error is detected. Here, an error non-detection notification signal may indicate a signal for notifying of non-detection of an error, and an error detection notification signal may indicate a signal for notifying of detection of an error.

The blanking signal generation unit 1 re-transmits the blanking signal that has been specified by the error notification signal to the blanking deflector 2 through the transmission path 14. The blanking deflector 2 receives the re-transmitted blanking signal at the blanking signal re-transmission receiving unit 9 and transmits the received blanking signal to the buffer memory 5 in a transmission path that corresponds to that blanking signal. The buffer memory 5 has a first-in first-out (FIFO) structure capable of retaining a plurality of units' worth of blanking signals and transmits a normally received re-transmitted blanking signal sequentially to the application voltage generation unit 6 provided in a later stage. Note that a blanking signal in which an error has occurred may be corrected by a normally received re-transmitted blanking signal at the final stage in the buffer memory 5. Here, the capacity of the buffer memory 5 (i.e., the number of transmission units of blanking signals that can be retained) may be set to be the capacity that allows information, which is received within the maximum allowable time from the error detection until the error correction, to be retained (i.e., the number of transmission units of the blanking signals that can be received within that time). Accordingly, the drawing apparatus does not necessarily need to be stopped or put on stand-by when an error is detected. This can realize a drawing apparatus that has advantages in an operation rate even with a communication error.

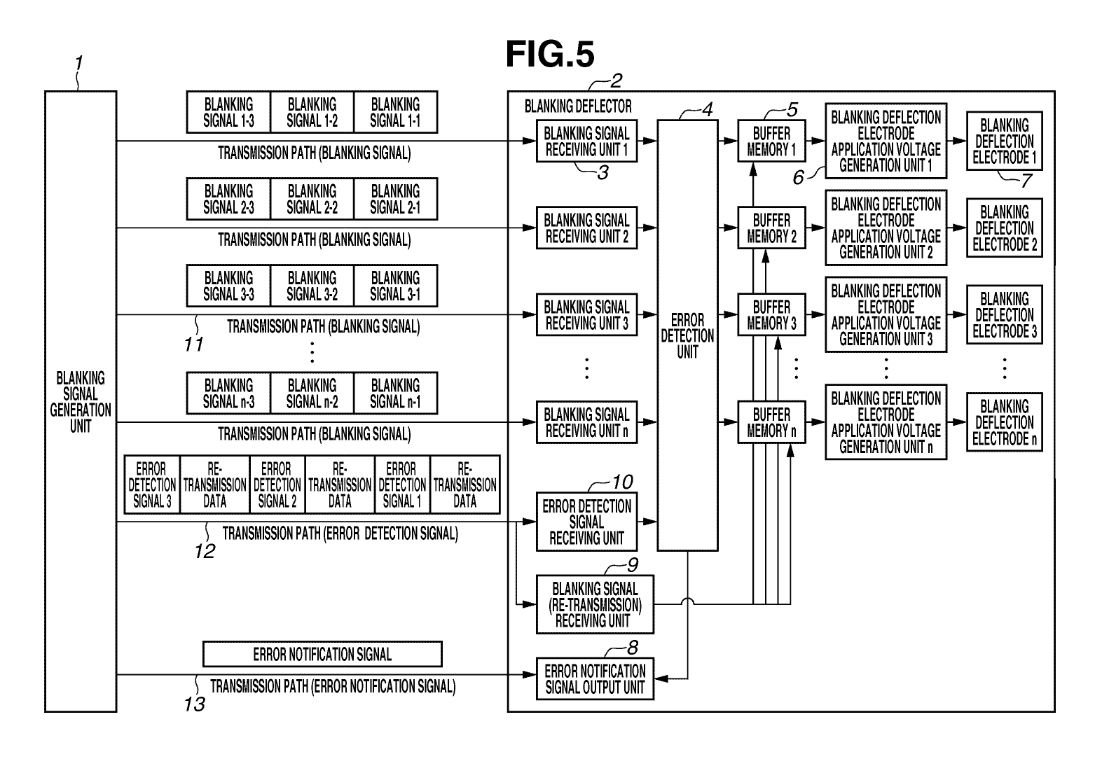

A method for transmitting a blanking signal and an error detection signal according to a second exemplary embodiment of the present invention will now be described with reference to FIG. 5. FIG. 5 illustrates a configuration example of a main portion according to the second exemplary embodiment and the signal transmission therein. FIG. 5 illustrates various signals generated by the blanking signal generation unit 1 and the blanking deflector 2 and transmission of these signals.

The second exemplary embodiment is similar to the first exemplary embodiment in that the transmission paths 11 for transmitting the blanking signals, the transmission path 12 for transmitting the error detection signals, and the transmission path 13 for transmitting the error notification signal are provided separately. However, although the transmission path 14 for re-transmitting a blanking signal is provided separately from the aforementioned transmission paths 11, 12, and 13 in the first exemplary embodiment, the second exemplary embodiment differs from the first exemplary embodiment in that a transmission path for re-transmitting a blanking signal is not separately provided. As described above, in the drawing apparatus that performs drawing with a plurality of electron beams, the number of transmission paths 11 required for transmitting the blanking signals becomes large, and thus it is desirable to reduce the number of other transmission paths as much as possible. Accordingly, in the second exemplary embodiment, the transmission path is commonly used for transmitting an error detection signal and for re-transmitting a blanking signal.

In the first exemplary embodiment, if the data length of an error detection signal that includes an error detection code is shorter than the data length of a blanking signal based on which the error detection signal is generated, information or a code other than the error detection code is added to the error detection signal to match the data length thereof with the data length of the blanking signal. On the other hand, in the second exemplary embodiment, the blanking signal generation unit 1 re-transmits a blanking signal through the transmission path 12 for transmitting the error detection signals by using a data length that is still left unoccupied by an error detection code or other information such as the error detection code and an identification signal of the blanking signal. For example, the blanking signal generation unit 1 may generate a packet that includes an error detection signal and a blanking signal to be re-transmitted and transmit the packet. In this case, there is of course a limit to the stated unoccupied data length. Therefore, if the unoccupied data length is not sufficient, the blanking signal to be re-transmitted may be divided and then re-transmitted. Here, if the blanking signal is divided and then re-transmitted, the transmission speed is lower (i.e., it takes a longer time to re-transmit the blanking signal), in comparison with the case where the blanking signal is re-transmitted all at once through the dedicated transmission path 14 as in the first exemplary embodiment. Therefore, it is desirable to keep the data length of the blanking signal to be re-transmitted as short as possible and to keep the number of pieces into which the blanking signal is divided as small as possible.

According to the second exemplary embodiment, the common transmission path 12 is used to transmit the error detection signals and to re-transmit the blanking signals, and thus a similar effect to that of the first exemplary embodiment can be achieved with a smaller number of transmission paths.

A method for manufacturing an article according to a third exemplary embodiment of the present invention is suitable for manufacturing micro devices such as a semiconductor device, devices having a fine structure, and so forth. Such a method may include forming a latent image pattern on a substrate coated with a photosensitive material using the above-described drawing apparatus (i.e., performing drawing on the substrate) and developing the substrate on which the latent image pattern has been formed. The method may further include other publicly-known procedures such as oxidation, deposition, vapor deposition, doping, planarization, etching, resist stripping, dicing, bonding, packaging, and so forth. The method for manufacturing an article according to the exemplary embodiment has advantages in terms of at least one of performance, quality, productivity, and production cost of the article in comparison with an existing method.

For example, the correspondence relationship between a transmission path for transmitting a blanking signal and the blanker electrode may be realized on various modes. The correspondence relationship between such a transmission path and a blanker electrode may be, but is not limited to, 1 to 1 or 1 to N (N is an integer equal to or greater than 2). Here, a single packet that includes a blanking signal may, but is not limited to, contain data worth a single row or a plurality of rows (i.e., one scan or a plurality of scans) of corresponding one or N blanker electrode(s). Further, a plurality of blanker electrodes (blanker electrode array) to be used for drawing may be managed in blocks of a plurality of sub-arrays. In that case, the correspondence relationship between the aforementioned transmission path and the sub-arrays of the blanker electrodes may be, but is not limited to, 1 to 1 or 1 to M (M is an integer equal to or greater than 2). Here, a single packet that includes a blanking signal may, but is not limited to, contain data worth a single row or a plurality of rows (i.e., one scan or a plurality of scans) of blanker electrodes included in corresponding one or M sub-arrays.

Furthermore, the exemplary embodiments of the present invention provide an advantageous technique that completes transmission of a large amount of data in a short period of time, and thus the exemplary embodiments can be applied not only to a charged particle beam drawing apparatus but, more widely, to apparatuses that can advantageously adopt the transmission technique described above. The blanking signal generation unit 1 and the blanking deflector 2 of the exemplary embodiments described above respectively correspond to a transmission apparatus and a receiving apparatus in a system that requires communication (transmission). Accordingly, the exemplary embodiments of the present invention can more generally be applied to a transmission apparatus. In that case, the transmission apparatus includes a generation device configured to generate a second signal (error detection signal in the above-described exemplary embodiments) for detecting an error with respect to a first signal (blanking signal in the above-described exemplary embodiments) to be transmitted. Then, the transmission apparatus may be configured to transmit the first signal and the second signal through a first transmission path and a second transmission path, respectively, in parallel to a receiving apparatus. Similarly, the exemplary embodiments of the present invention can more generally be applied to a receiving apparatus. In that case, the receiving apparatus may include a receiving device configured to receive a first signal and a second signal through a first transmission path and a second transmission path, respectively. Then, the receiving apparatus may further include a detection unit configured to detect an error with respect to a signal received by the receiving device based on the first signal and information for detecting the error contained in the second signal. In the exemplary embodiments described above, if the receiving apparatus detects an error, the receiving apparatus requests the transmission apparatus to re-transmit the signal. However, such a configuration may be replaced by or may further include a configuration in which the transmission apparatus additionally transmits an error correction code and the receiving apparatus carries out the correction based on the received error correction code. At least one of the transmission apparatus, the receiving apparatus, and a system that includes the transmission apparatus and the receiving apparatus has advantages in terms of throughput of communication processing even with a communication error.

A specific example of an apparatus that includes at least one of the transmission apparatus and the receiving apparatus described above may include a maskless lithography apparatus, aside from a charged particle beam drawing apparatus, for directly drawing an electronic circuit pattern on a substrate such as a wafer without using a photomask. Such a maskless lithography apparatus may include a digital light processing (DLP) device that is based on a digital mirror device (DMD). Further, such a maskless lithography apparatus may include a lithography apparatus that directly draws a pattern on a substrate with a plurality of laser beams. Another specific example of an apparatus that includes at least one of the transmission apparatus and the receiving apparatus described above may include a large-capacity storage device or a high-speed computer. Yet another specific example may include a transmission device that transmits data between a large-capacity storage device and a high-speed computer, between large-capacity storage devices, or between high-speed computers.

In addition, in the description above, the blanker array 106 has been illustrated as an array of electrode pairs that can be driven individually, but without being limited thereto, the blanker array 106 may simply be an array of elements having a blanking function. For example, the blanker array 106 may include such a reflective electron patterning device as discussed in U.S. Pat. No. 7,816,655. Such a device includes a pattern on a top surface, an electron reflective portion of that pattern, and an electron non-reflective portion of that pattern. Such a device may further include an array of circuitry for dynamically modifying the electron reflective portion and the electron non-reflective portion of the aforementioned pattern using a plurality of pixels that can be controlled independently from one another. In this way, the blanker array 106 may be an array of elements (blankers) that blanks the charged particle beams by changing a reflective portion, which is reflective to the charged particle beams, to a non-reflective portion. Note that it is apparent that the configuration of the charged electron optical system that includes such a reflective device may differ from the configuration of the charged electron optical system that includes a transmissive device such as an electrode pair array.

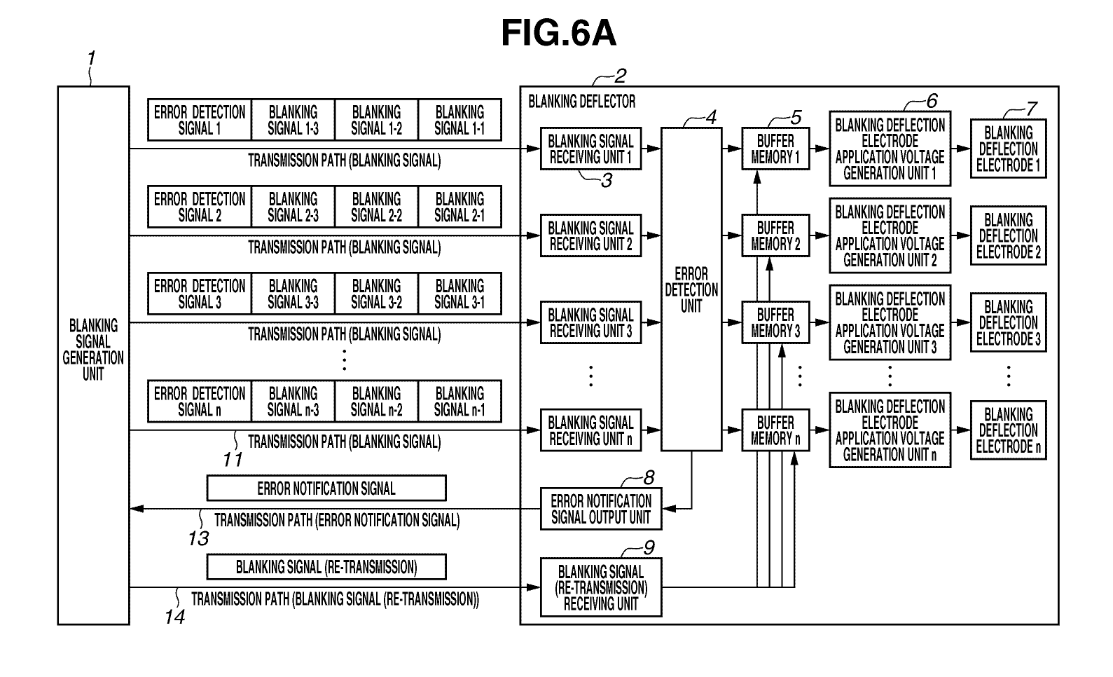

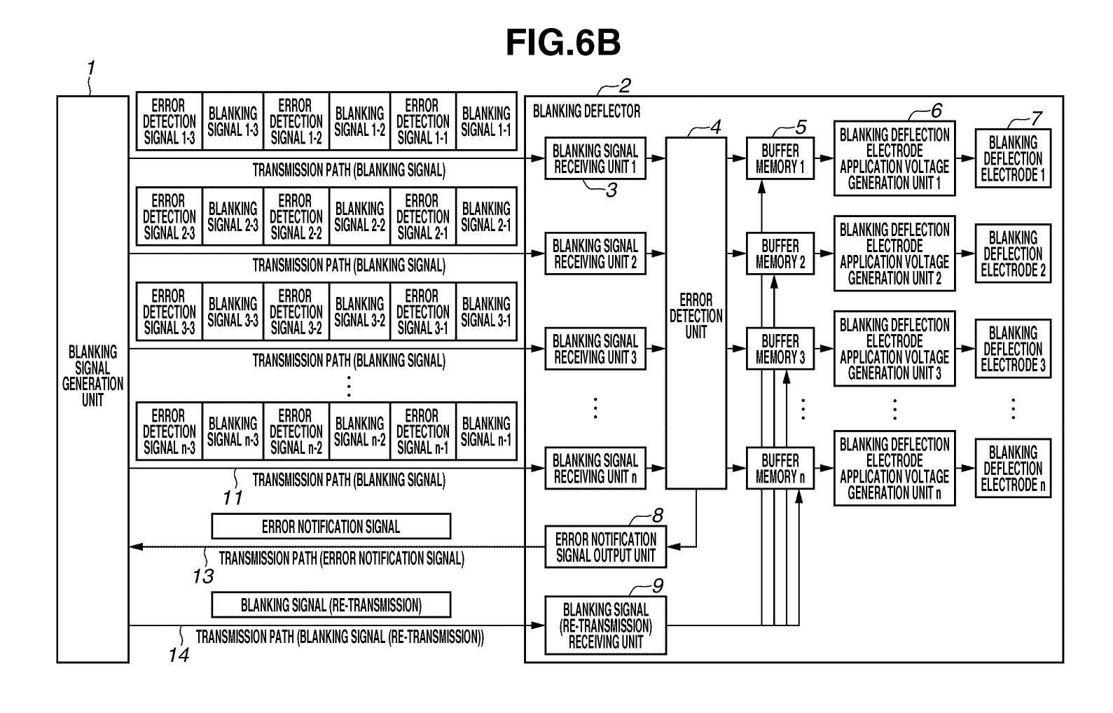

Now, advantageous effects of the exemplary embodiments described above will further be described. Handling of an error in a blanking control signal may require a detection time from when reception of the blanking control signal of a predetermined unit amount is completed until detection of an error is completed and a re-transmission time from when the detection is completed until the re-transmission of a signal is completed. In a comparative example illustrated in FIG. 6A, a blanking signal is retained in the buffer memory 5 after the error detection unit 4 detects an error until blanking is carried out. The buffer memory 5, for example, has an FIFO structure capable of retaining a predetermined amount of blanking signals (for example, n times an error detection unit amount, where n is a natural number), and sequentially outputs the blanking signals to a later-stage unit (e.g., the application voltage generation unit 6). If the time from when the error detection is completed until the re-transmission is completed exceeds normal duration in which the buffer memory 5 can retain the blanking signal of a predetermined amount, a drawing operation needs to be stopped or put on stand-by in order to avoid blanking with an erroneous blanking signal. This may cause the throughput to be lowered. Further, if the number of error detection signals is increased as in a comparative example illustrated in FIG. 6B, a total signal amount including the blanking signals and the error detection signals increases. Thus, if the capacity (or the number) of the transmission paths remains the same, time required for transmitting signals increases, and as a result, the blanking frequency for performing drawing is reduced, which may affect the throughput of the drawing apparatus.

On the other hand, with the above-described exemplary embodiments, the drawing apparatus does not necessarily need to be stopped or put on stand-by when an error is detected, or duration in which a drawing operation is stopped or put on stand-by can be reduced. This can provide a drawing apparatus that has advantages in the operation rate even with a communication error. As the detection time is shorter, the re-transmission can be completed more quickly, and thus the aforementioned stopping or stand-by can be avoided, or the duration of the stopping or stand-by can be shortened.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-158514 filed Jul. 17, 2012, which is hereby incorporated by reference herein in its entirety.

What is claimed is:

1. A drawing apparatus that performs drawing on a substrate with a plurality of charged particle beams, the drawing apparatus comprising:
a blanking deflector configured to blank the plurality of charged particle beams, respectively;
a generating device configured to generate a blanking signal for controlling the blanking deflector and an error detection signal for the blanking signal; and
a plurality of transmission paths for transmitting signals between the generating device and the blanking deflector,
wherein the plurality of transmission paths include a first transmission path for transmitting the blanking signal and a second transmission path for transmitting the error detection signal, and
wherein the generating device is configured to transmit the blanking signal and the error detection signal via the first transmission path and the second transmission path, respectively, to the blanking deflector in parallel.

2. The drawing apparatus according to claim 1, wherein the first transmission path includes a plurality of blanking signal transmission paths for transmitting the blanking signals from the generating device to the blanking deflector in parallel, and
wherein the generating device is configured to transmit, via the second transmission path, the error detection signals that respectively correspond to the plurality of blanking signals to be respectively transmitted to the plurality of blanking signal transmission paths.

3. The drawing apparatus according to claim 1, wherein the generating device is configured to transmit the blanking signal and the error detection signal in synchronization with each other.

4. The drawing apparatus according to claim 1, wherein the second transmission path is dedicated for transmission of the error detection signal.

5. The drawing apparatus according to claim 1, wherein the blanking deflector is configured to perform error detection for the blanking signal based on the blanking signal and the error detection signal, and to transmit an error notification signal to the generating device, if an error is detected by the error detection, and
wherein the generating device is configured to perform re-transmission of the blanking signal based on the error notification signal.

6. The drawing apparatus according to claim 5, wherein the generating device is configured to perform the re-transmission of the blanking signal via the second transmission path.

7. The drawing apparatus according to claim 6, wherein the generating device is configured to transmit, via the second transmission path, a packet that includes the error detection signal and the blanking signal pertaining to the re-transmission.

8. A method of manufacturing an article, the method comprising:
performing drawing on a substrate using a drawing apparatus;
developing the substrate on which the drawing has been performed; and
processing the developed substrate to manufacture the article,
wherein the drawing apparatus performs the drawing with a plurality of charged particle beams, the drawing apparatus including:
a blanking deflector configured to blank the plurality of charged particle beams, respectively;
a generating device configured to generate a blanking signal for controlling the blanking deflector and an error detection signal for the blanking signal; and
a plurality of transmission paths for transmitting signals between the generating device and the blanking deflector,
wherein the plurality of transmission paths includes a first transmission path for transmitting the blanking signal and a second transmission path for transmitting the error detection signal, and
wherein the generating device is configured to transmit the blanking signal and the error detection signal via the first transmission path and the second transmission path, respectively, to the blanking deflector in parallel.

9. A transmission apparatus, comprising:
a generating device configured to generate a second signal for detecting an error for a first signal to be transmitted,
wherein the transmission apparatus is configured such that the first signal and the second signal are transmitted via a first transmission path and a second transmission path, respectively, to a receiving apparatus in parallel.

10. A receiving apparatus, comprising:
a receiving device configured to receive a first signal and a second signal via a first transmission path and a second transmission path, respectively; and
a detection device configured to perform error detection for a signal received by the receiving device based on the first signal and a signal, included in the second signal, for error detection for the first signal.

11. A drawing apparatus that performs drawing on a substrate with a plurality of charged particle beams, the drawing apparatus comprising:
a blanker array configured to blank the plurality of charged particle beams, respectively;
a generating device configured to generate a blanking signal for controlling the blanker array and an error detection signal for the blanking signal; and
a plurality of transmission paths for transmitting signals between the generating device and the blanker array,
wherein the plurality of transmission paths include a first transmission path for transmitting the blanking signal and a second transmission path for transmitting the error detection signal, and
wherein the generating device is configured to transmit a blanking signal and an error detection signal corresponding to the blanking signal via the first transmission path and the second transmission path, respectively, to the blanker array in parallel.

12. The drawing apparatus according to claim 11, wherein the plurality of transmission paths include a plurality of first transmission paths for transmitting the blanking signals and the second transmission path for transmitting the error detection signal, and
wherein the generating device is configured to transmit a plurality of blanking signals and an error detection signal corresponding to the plurality of blanking signals via the plurality of first transmission paths and the second transmission path, respectively, to the blanker array in parallel.

13. The drawing apparatus according to claim 11, wherein the generating device is configured to transmit a blanking signal and an error detection signal corresponding to the blanking signal in synchronization with each other.

14. The drawing apparatus according to claim 11, wherein the second transmission path is dedicated for transmission of the error detection signal.

15. The drawing apparatus according to claim 11, wherein the blanker array is configured to perform error detection for a blanking signal based on the blanking signal and an error detection signal corresponding to the blanking signal, and to transmit an error notification signal to the generating device, if an error is detected by the error detection, and
wherein the generating device is configured to perform re-transmission of the blanking signal based on the error notification signal.

16. The drawing apparatus according to claim 15, wherein the generating device is configured to perform the re-transmission of the blanking signal via the second transmission path.

17. The drawing apparatus according to claim 16, wherein the generating device is configured to transmit, via the second transmission path, a packet that includes the error detection signal and the blanking signal pertaining to the re-transmission.

18. A method of manufacturing an article, the method comprising:
performing drawing on a substrate using a drawing apparatus;
developing the substrate on which the drawing has been performed; and
processing the developed substrate to manufacture the article,
wherein the drawing apparatus performs the drawing with a plurality of charged particle beams, the drawing apparatus including:
a blanker array configured to blank the plurality of charged particle beams, respectively;
a generating device configured to generate a blanking signal for controlling the blanker array and an error detection signal for the blanking signal; and
a plurality of transmission paths for transmitting signals between the generating device and the blanker array,
wherein the plurality of transmission paths include a first transmission path for transmitting the blanking signal and a second transmission path for transmitting the error detection signal, and
wherein the generating device is configured to transmit a blanking signal and an error detection signal corresponding to the blanking signal via the first transmission path and the second transmission path, respectively, to the blanker array in parallel.
